(19) United States
(12) Patent Application Publication
(10) Pub. No.: US 2024/0143857 A1
(43) Pub. Date: May 2, 2024

(54) SPATIAL INFORMATION OUTPUT METHOD, SPATIAL INFORMATION OUTPUT DEVICE, AND COMPUTER-READABLE RECORDING MEDIUM RECORDING A PROGRAM

(71) Applicant: Panasonic Intellectual Property Corporation of America, Torrance, CA (US)

(72) Inventors: Hiroko Izumi, Kanagawa (JP); Tatsumi Nagashima, Osaka (JP); Mitsuko Shuto, Osaka (JP)

(21) Appl. No.: 18/402,927

(22) Filed: Jan. 3, 2024

Related U.S. Application Data
(63) Continuation of application No. PCT/JP2022/026610, filed on Jul. 4, 2022.

(30) Foreign Application Priority Data
Jul. 9, 2021 (JP) 2021-114411

(51) Int. Cl. G06F 30/13

(52) U.S. Cl. CPC G06F 30/13

(57) ABSTRACT

An information processing apparatus acquires first spatial information including division information indicative of divisions in a building and device-installation information indicative of a device or an installation disposed in a division; acquires space use information associating the device-installation information and use information indicative of a space use in connection with a device or an installation disposed in a space with each other; generates second spatial information by associating the use information with the division information included in the first spatial information on the basis of the space use information; and outputs the second spatial information.

### TECHNICAL FIELD

The present disclosure relates to a space information output method, a space information output apparatus, and a computer-readable recording medium recording a program.

### BACKGROUND ART

Patent Literature 1 discloses a technique of suggesting a living space on the basis of information on a preference of a user.

However, in Patent Literature 1, no consideration can be seen to set a use of each space in connection with a device or an installation disposed in each space of a building.

### CITATION LIST

### Patent Literature

Patent Literature 1: International Unexamined Patent Publication WO 2018/139293

### SUMMARY OF INVENTION

An object of the present disclosure is to provide a space information output method, a space information output apparatus, and a computer-readable recording medium recording a program that enable setting of a use of each division in connection with a device or an installation disposed in each division of a building.

A space information output method according to a feature of the present disclosure, by an information processing apparatus, includes: acquiring first spatial information including division information indicative of divisions in a building and device-installation information indicative of a device or an installation disposed in a division; acquiring space use information associating the device-installation information and use information indicative of a space use in connection with a device or an installation disposed in a space with each other; generating second spatial information by associating the use information with the division information included in the first spatial information on the basis of the space use information; and outputting the second spatial information.

### BRIEF DESCRIPTION OF DRAWINGS

FIG. 1 is a diagram showing a whole structure of a home control system according to a first embodiment.

FIG. 2 is a diagram briefly showing a structure of a server device according to the first embodiment.

FIG. 3 is a flowchart briefly showing a flow of a process executed by an information processing part of the server device according to the first embodiment.

FIG. 4 is a flowchart showing in detail a proceeding shown in FIG. 3.

FIG. 5 is a diagram briefly showing an example of first spatial information.

FIG. 6 is a diagram briefly showing an exemplary relevance table.

FIG. 7 is a flowchart showing in detail a proceeding shown in FIG. 3.

FIG. 8 is a diagram briefly showing an example of space use information.

FIG. 9 is a diagram showing a first example of second spatial information.

FIG. 10 is a diagram showing a second example of the second spatial information.

FIG. 11 is a diagram briefly showing a structure of a server device according to a second embodiment.

FIG. 12 is a flowchart briefly showing a flow of a process executed by an information processing part of the server device according to the second embodiment.

FIG. 13 is a flowchart showing in detail a first example of a proceeding shown in FIG. 12.

FIG. 14 is a diagram briefly showing an example of similarity information.

FIG. 15 is a diagram showing an exemplary combination proceeding.

FIG. 16 is a diagram briefly showing an example of third spatial information.

FIG. 17 is a flowchart showing in detail a second example of the proceeding shown in FIG. 12.

FIG. 18 is a diagram briefly showing an example of relevance information.

FIG. 19 is a diagram showing an exemplary combination proceeding.

### DESCRIPTION OF EMBODIMENTS

Underlying Findings for Present Disclosure

In a smart home provided with an IoT device, an integral controller enables centralized management and control of operations of devices that are the target of the control and disposed in respective spaces, e.g., an entrance, corridor, or a room.

A task (room partitioning) of dividing beforehand a plurality of spaces defined in the smart home into spatial units that are the target of the management is required to achieve such control. Conventionally, an operator or a user has performed a manual room partitioning for the smart home while referring to, e.g., an architectural blueprint; this task is complicated and inefficient.

To solve the above-mentioned problems, the present inventors found that use information can be automatically set on each space by utilizing device-installation information indicative of a device or an installation disposed in each space of a building in a case that the device-installation information is included in a blueprint of the building, thus achieving the present disclosure.

Next, embodiments of the present disclosure will be described.

A space information output method according to a first feature of the present disclosure, by an information processing apparatus, includes: acquiring first spatial information including division information indicative of divisions in a building and device-installation information indicative of a device or an installation disposed in a division; acquiring space use information associating the device-installation information and use information indicative of a space use in connection with a device or an installation disposed in a space with each other; generating second spatial information by associating the use information with the division information included in the first spatial information on the basis of the space use information; and outputting the second spatial information.

In the first feature, the information processing apparatus acquires the first spatial information including the division information and the device-installation information and the space use information associating the device-installation information and the use information with each other. The information processing apparatus generates the second spatial information by associating the use information with the division information included in the first spatial information on the basis of the space use information. Thus, use information for a division covered by the first spatial information can be automatically set by use of the device-installation information included in the first spatial information. This can make the setting task easier and more efficient.

With a space information output method according to a second feature of the present disclosure, in the first feature, in the acquisition of the first spatial information, a blueprint or a floor plan of the building may be acquired, a space separated by a wall or a partition in the blueprint or the floor plan may be detected as a division, and device-installation information in the division may be detected.

In the second feature, a division and device-installation information are detected from the blueprint or the floor plan of the building. This enables easy and efficient acquisition of the first spatial information.

A space information output method according to a third feature of the present disclosure may, in the second feature, further include: assigning identification information to the division, and creating a relevance table associating the identification information and the device-installation information with each other.

In the third feature, a relevance table associating the identification information of the division and the device-installation information with each other is created. This enables easy management of an association between a division and device-installation information.

With a space information output method according to a fourth feature of the present disclosure, in the second or third feature, the device-installation information may include any one of an illustration, a sign, and a name indicative of a placed device or installation in the blueprint or the floor plan.

The fourth feature enables use of an illustration, a sign, and a name for a device or an installation included in the blueprint or the floor plan as device-installation information.

With a space information output method according to a fifth feature of the present disclosure, in any one of the first to fourth features, in the generation of the second spatial information, the device-installation information included in the space use information may be collated with the device-installation information for the division in the first spatial information, and in a case that the device-installation information included in the space use information concerns the division covered by the first spatial information, the division may be associated with use information which is associated with the device-installation information in the space use information.

In the fifth feature, in a case that the device-installation information included in the space use information concerns the division covered by the first spatial information, the division is associated with use information which is associated with the device-installation information in the space use information. This enables an easy association of each division covered by the first spatial information with appropriate use information.

With a space information output method according to a sixth feature of the present disclosure, in the fifth feature, in a case that the device-installation information included in the space use information does not concern the division covered by the first spatial information, the division may be associated with use information indicative of multiple space uses.

In the sixth feature, in a case that the device-installation information included in the space use information does not concern the division covered by the first spatial information, the division is associated with use information indicative of multiple space uses. This can prevent an association of a division without device-installation information with wrong use information.

A space information output method according to a seventh feature of the present disclosure may, in any one of the first to sixth features, further include: generating, in a case that the second spatial information includes a plurality of divisions adjacent to each other and assigned with identical or similar use information, third spatial information on combination of the plurality of divisions; and outputting the third spatial information.

In the seventh feature, in a case that the second spatial information includes a plurality of divisions adjacent to each other and assigned with identical or similar use information, the information processing apparatus generates third spatial information on combination of the plurality of divisions. This enables optimized spatial management based on the use information. Consequently, the usability for a user can be improved.

A space information output method according to an eighth feature of the present disclosure may, in any one of the first to sixth features, further include: generating, in a case that the second spatial information includes a plurality of divisions adjacent to each other and provided with identical or relevant devices or installations, third spatial information on combination of the plurality of divisions; and outputting the third spatial information.

In the eighth feature, in a case that the second spatial information includes a plurality of divisions adjacent to each other and provided with identical or relevant devices or installations, the information processing apparatus generates third spatial information on combination of the plurality of divisions. This enables optimized spatial management based on relevance information on a device or an installation. Consequently, the usability for a user can be improved.

With a space information output method according to a ninth feature of the present disclosure, in the eighth feature, the relevant device or installation may include a light, a wire connected to the light, and a switch connected to the wire.

The ninth feature enables a combination of a plurality of divisions across which a light, a wire, and a switch are provided into one division.

With a space information output method according to a tenth feature of the present disclosure, in any one of the first to ninth features, the space use information may include the use information indicative of at least one of an entrance, a washroom, a kitchen, a dining room, a living room, a bedroom, a bathroom, and a Japanese-style room.

In the tenth feature, a typical spatial name serving as use information can be associated with division information. Thus, the usability for a user can be improved.

A space information output apparatus according to an eleventh feature of the present disclosure includes: an acquisition part for acquiring first spatial information including division information indicative of divisions in a building and device-installation information indicative of a device or an installation disposed in a division, and space use information associating the device-installation information and use information indicative of a space use in connection with a device or an installation disposed in a space with each other; a setting part for generating second spatial information by associating the use information with the division information included in the first spatial information on the basis of the space use information; and an output part for outputting the second spatial information.

In the eleventh feature, the acquisition part acquires the first spatial information including the division information and the device-installation information, and the space use information associating the device-installation information and the use information with each other. The setting part generates second spatial information by associating the use information with the division information included in the first spatial information on the basis of the space use information. Thus, use information for a division covered by the first spatial information can be automatically set by use of the device-installation information included in the first spatial information. This can make the setting task easier and more efficient.

A program according to a twelfth feature of the present disclosure causes an information processing apparatus to serve as: acquisition means for acquiring first spatial information including division information indicative of divisions in a building and device-installation information indicative of a device or an installation disposed in a division, and space use information associating the device-installation information and use information indicative of a space use in connection with a device or an installation disposed in a space with each other; setting means for generating second spatial information by associating the use information with the division information included in the first spatial information on the basis of the space use information; and output means for outputting the second spatial information.

In the twelfth feature, the acquisition means acquires the first spatial information including the division information and the device-installation information, and the space use information associating the device-installation information and the use information with each other. The setting means generates second spatial information by associating the use information with the division information included in the first spatial information on the basis of the space use information. Thus, use information for a division covered by the first spatial information can be automatically set by use of the device-installation information included in the first spatial information. This can make the setting task easier and more efficient.

This disclosure can be realized as: a program for causing a computer to execute each distinctive feature included in such a method or an apparatus; or a system operated by the program. Additionally, it goes without saying that the program is distributable as a non-transitory computer readable storage medium like a CD-ROM, or distributable via a communication network like the Internet.

### Embodiments of Present Disclosure

Embodiments of the present disclosure will be described below with reference to the drawings. The elements given the same reference numerals in different drawings are defined to be the same or like elements. Constituent elements, dispositions thereof, connections between them, and the order of operations described below are mere examples, and thus should not be construed to delimit the disclosure. Only the claims delimit the present disclosure. Hence, constituent elements which are not recited in the independent claims each showing the broadest concept among the constituent elements in the embodiments are described as being ones not necessarily required to accomplish the object of the present disclosure but required to achieve preferable configurations.

### First Embodiment

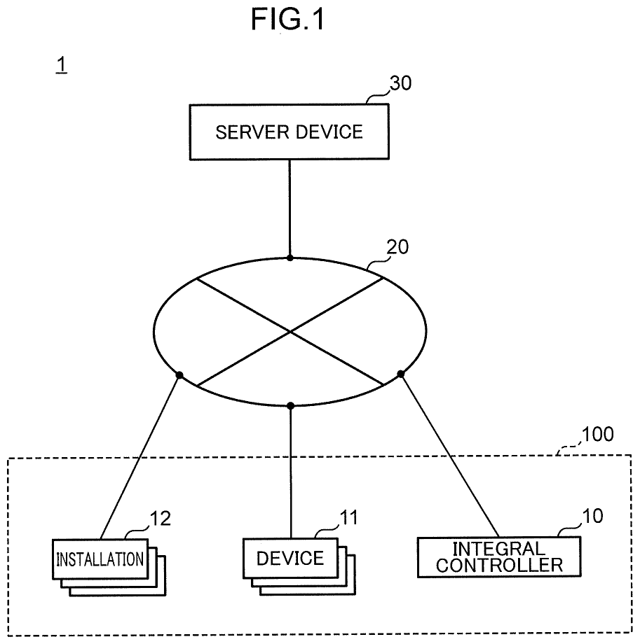

FIG. 1 is a diagram showing a whole structure of a home control system 1 according to a first embodiment of the present disclosure. The home control system 1 includes a server device 30, and a plurality of devices 11 and a plurality of installations 12 disposed in a smart home 100. The devices 11 and the installations 12 are connected to the server device 30 through a communication network 20 such as a public network. Only one smart home 100 is shown in FIG. 1 for a brief explanation, but a plurality of smart homes 100 may be included. The present disclosure can be applied to a house such as a smart home 100, and to an indoor facility, e.g., an office, a restaurant, a commercial facility, but is not limited to the indoor facility and can be applied to a space having both an indoor space and an outdoor space.

The smart home 100 has a plurality of spaces, e.g., a room, a bathroom, a toilet, an entrance, or a corridor. The devices 11 and the installations 12 are disposed in the respective spaces. The devices 11 include an electronic device, e.g., a home appliance. The electronic device includes IoT devices, e.g., an air conditioner, a TV, a refrigerator, a rice cooker, a microwave oven, and a light. The installations 12 include an appliance or furniture used in a location where it is provided.

The smart home 100 includes an integral controller 10 for controlling a device 11 and an installation 12 that are the control target among the devices 11 and the installations 12. The integral controller 10 can perform mutual data communication with a device 11 and an installation 12 that are the control target through the communication network 20 or a wireless LAN.

The server device 30 is a cloud server or an edge server and manages the whole home control system 1. The server device 30 can perform mutual data communication with the integral controller 10, the devices 11, and the installations 12 through the communication network 20. The functions of the server device 30 may be included in the integral controller 10.

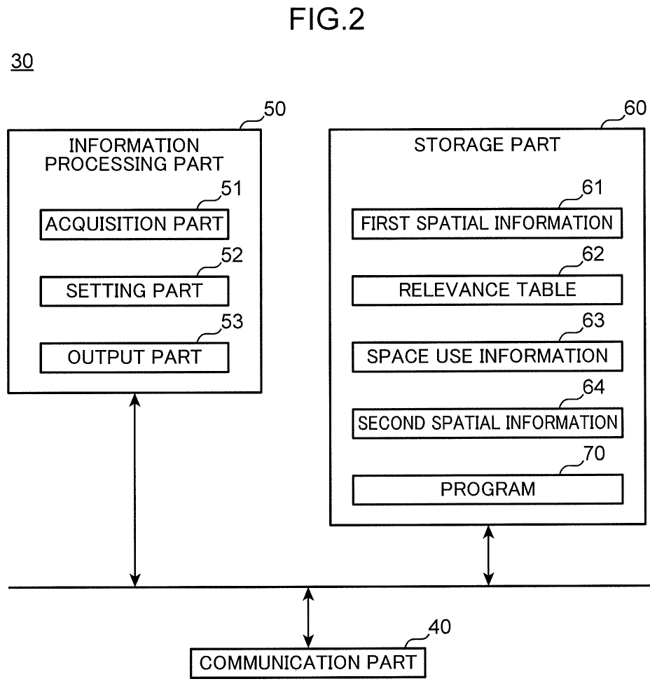

FIG. 2 is a diagram briefly showing a structure of the server device 30 according to the first embodiment. The server device 30 includes a communication part 40, an information processing part 50, and a storage part 60.

The communication part 40 includes a communication module compatible with a communication system such as an IP.

The storage part 60 includes, for example, an HDD, an SSD, or a flash memory. The storage part 60 stores first spatial information 61, a relevance table 62, space use information 63, second spatial information 64, and a program 70. The first spatial information 61, the relevance table 62, the space use information 63, and the second spatial information 64 will be described later.

The information processing part 50 includes a processor such as a CPU. The information processing part 50 includes an acquisition part 51, a setting part 52, and an output part 53, which are established by causing a CPU to execute the program 70 read in a ROM or a RAM from the storage part 60. In other words, the program 70 causes the information processing part 50 serving as the information processing apparatus and being provided in the server device 30 serving as the space information output apparatus to serve as the acquisition part 51, the setting part 52, and the output part 53. Although not shown in the drawings, the storage part 60 stores a blueprint or a floor plan of the smart home 100. The acquisition part 51 reads out and acquires the blueprint or the floor plan from the storage part 60. The acquisition part 51 detects a plurality of first spaces separated by a wall or a partition from the acquired blueprint or floor plan using a known technique of recognizing a space from a CAD drawing. The acquisition part 51 generates first spatial information 61 by assigning space identification information such as a space ID to each of the first spaces to thereby acquire the first spatial information 61. The setting part 52 defines a plurality of second spaces by associating each of the first spaces covered by the first spatial information 61 with use information with reference to the space use information 63 read out from the storage part 60 to generate second spatial information 64 covering the second spaces. The output part 53 outputs the second spatial information 64 generated by the setting part 52.

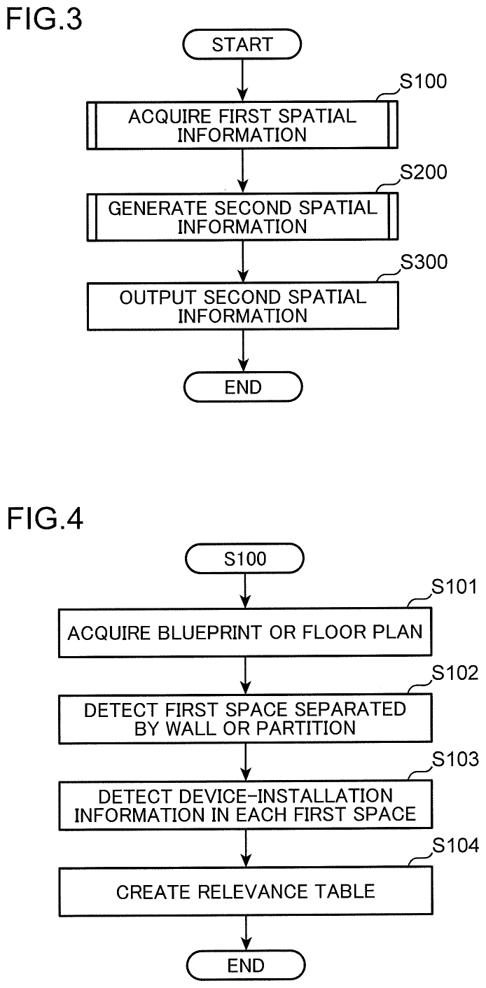

FIG. 3 is a flowchart briefly showing a flow of a process executed by the information processing part 50 of the server device 30 according to the first embodiment.

First, in Step S100, the acquisition part 51 acquires the first spatial information 61, and stores the acquired first spatial information 61 in the storage part 60. The details of Step S100 will be described later.

Next, in Step S200, the setting part 52 defines a plurality of second spaces by associating each of the first spaces covered by the first spatial information 61 with use information on the basis of the space use information 63 to generate second spatial information 64 covering the second spaces. The details of Step S200 will be described later.

Next, in Step S300, the output part 53 outputs the second spatial information 64 generated by the setting part 52. The second spatial information 64 output from the output part 53 is stored in the storage part 60. The second spatial information 64 output from the output part 53 is input to the communication part 40. The communication part 40 transmits the input second spatial information 64 to the integral controller 10 through the communication network 20. The communication part 40 may transmit the second spatial information 64 to a pre-registered communication terminal, e.g., a smartphone.

FIG. 4 is a flowchart showing in detail a proceeding of Step S100 shown in FIG. 3.

First, in Step S101, the acquisition part 51 acquires a blueprint or a floor plan of the smart home 100. Electronic data of the blueprint or the floor plan is created by scanning a paper version of the drawing, and the electronic data is stored in the storage part 60. The acquisition part 51 reads out and acquires the blueprint or the floor plan from the storage part 60.

Next, in Step S102, the acquisition part 51 detects a plurality of first spaces separated by a wall or a partition from the acquired blueprint or floor plan using a known technique of recognizing a space from a CAD drawing. The respective first spaces agree with the respective divisions in the smart home 100. The acquisition part 51 generates first spatial information 61 by assigning space identification information X such as a space ID to each of the first spaces to thereby acquire the first spatial information 61.

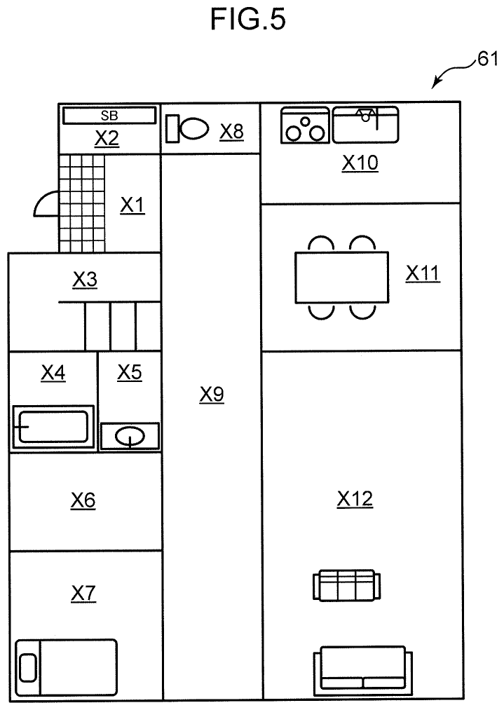

FIG. 5 is a diagram briefly showing an example of first spatial information 61. The first spatial information 61 includes division information indicative of divisions of the first spaces in the smart home 100. In the example, the first spatial information 61 covers twelve first spaces assigned with space identification information X1 to X12. The first spatial information 61 includes device-installation information indicative of a device or an installation disposed in each of the first spaces. The device-installation information includes any one of an illustration, a sign, and a name indicative of a device or an installation placed in respective rooms in the blueprint or the floor plan of the smart home 100. The device-installation information may include one used abroad as well as domestically in an architectural drawing.

Next, in Step S103, the acquisition part 51 detects device-installation information in each of the first spaces by image analysis of the first spatial information 61.

Next, in Step S104, the acquisition part 51 creates a relevance table 62 associating the space identification information X of the first space detected in Step S102 and the device-installation information detected in Step S103, and stores the created relevance table 62 in the storage part 60.

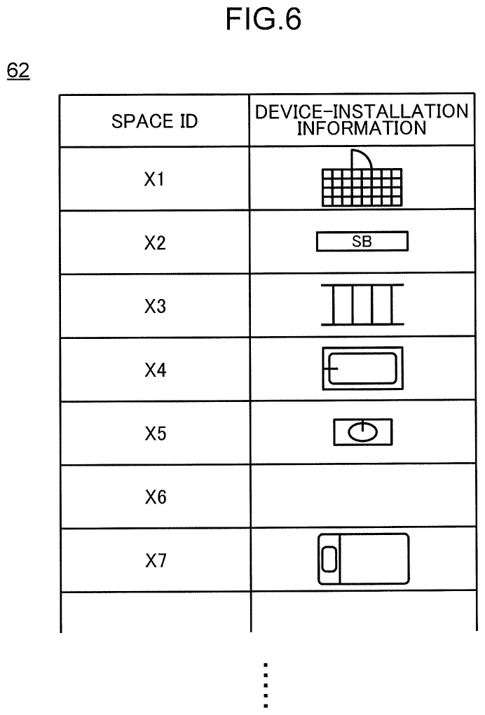

FIG. 6 is a diagram briefly showing an exemplary relevance table 62. The relevance table 62 specifies a relevance between the space identification information X such as a space ID and the device-installation information. For example, the space identification information (space ID) X1 is associated with device-installation information indicative of an entrance door and an entrance tile, and the space identification information X2 is associated with device-installation information indicative of a shoe rack (SB). The space identification information X3 is associated with device-installation information indicative of a stairway, the space identification information X4 is associated with device-installation information indicative of a bathtub, the space identification information X5 is associated with device-installation information indicative of a washbasin, and the space identification information X7 is associated with device-installation information indicative of a bed. Each space identification information X may be associated with a plurality of pieces of device-installation information. In the example in FIG. 5, since the first spaces assigned with the space identification information X6, X9 do not concern the device-installation information, the space identification information X6, X9 is not associated with the device-installation information, resulting in blanks in the relevance table 62.

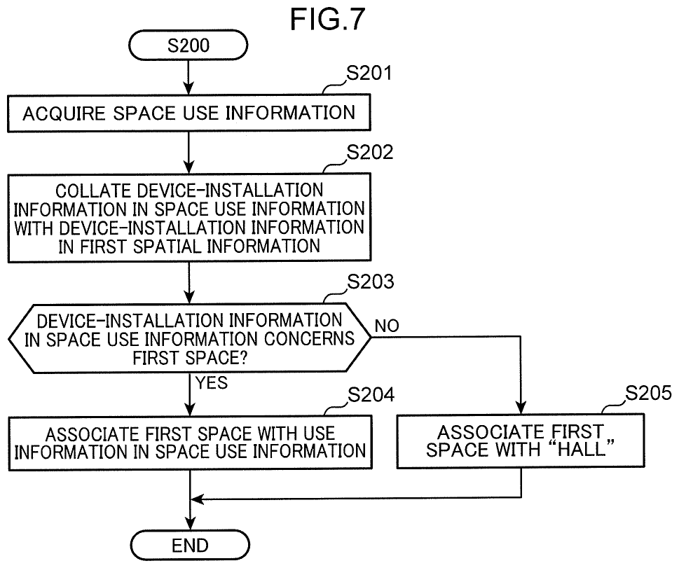

FIG. 7 is a flowchart showing in detail a proceeding of Step S200 shown in FIG. 3.

First, in Step S201, the setting part 52 reads out and acquires the space use information 63 from the storage part 60.

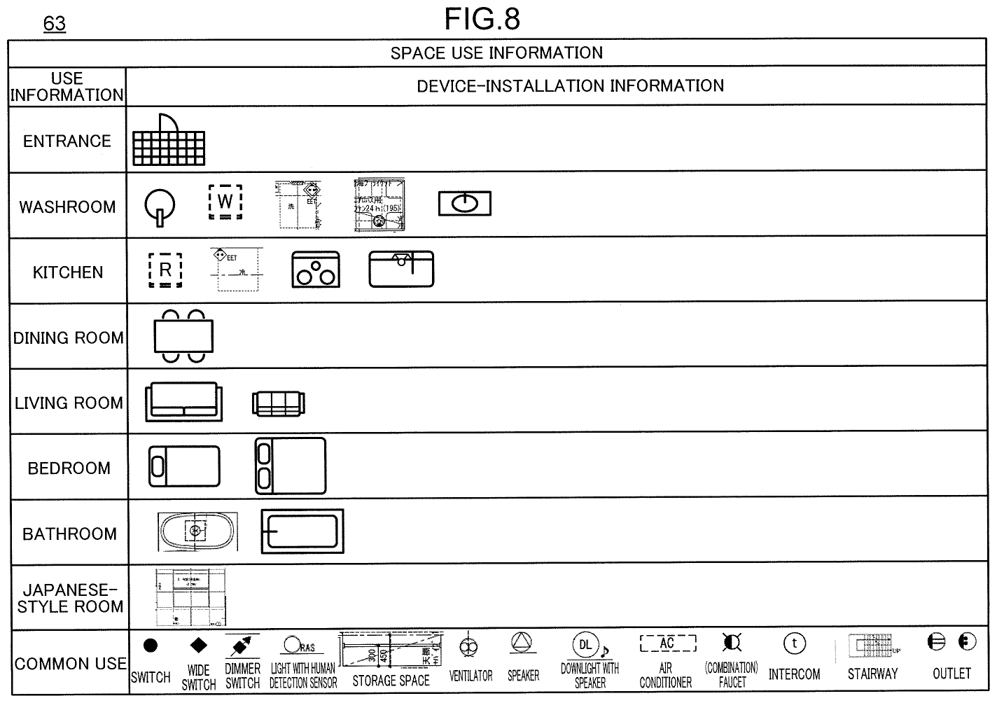

FIG. 8 is a diagram briefly showing an example of space use information 63. The space use information 63 specifies a relevance between various examples of the device-installation information and use information. The device-installation information is a preset or saved data group including any one of an illustration, a sign, and a name indicative of a device or an installation. The use information is information indicative of a space use in connection with a device or an installation disposed in a space. In the example, the use information concerns an entrance, a washroom, a kitchen, a dining room, a living room, a bedroom, a bathroom, and a Japanese-style room.

In the example of the space use information 63 shown in FIG. 8, the use information of entrance is associated with the device-installation information indicative of an entrance door and an entrance tile. The use information of washroom is associated with, e.g., the device-installation information indicative of a washbasin or device-installation information with “W” meaning a washing machine, which is indicative of a place for a washing machine. The use information of kitchen is associated with, e.g., device-installation information with “R” meaning a refrigerator, which is indicative of a place for a refrigerator, or device-installation information indicative of an induction cooker, a gas stove, or a sink. The use information of dining room is associated with device-installation information indicative of a dining table. The use information of living room is associated with device-installation information indicative of a sofa. The use information of bedroom is associated with device-installation information indicative of a bed. The use information of bathroom is associated with device-installation information indicative of a bathtub. The use information of Japanese-style room is associated with device-installation information indicative of a tatami.

The use information also includes a common use category, which is associated with device-installation information of, e.g., various switches, a light, a storage space, a ventilator, a speaker, a downlight, an air conditioner, a faucet, an intercom, a stairway, or an outlet that are not for a specific space only. The associations between the use information and the device-installation information shown in FIG. 8 are merely examples. The space use information 63 includes at least one of the associations, and may include an association other than the associations.

Next, in Step S202, the setting part 52 collates the device-installation information included in the space use information 63 with the device-installation information included in each of the first spaces covered by the first spatial information 61 with reference to the relevance table 62.

Next, in Step S203, the setting part 52 determines whether or not the device-installation information included in the space use information 63 concerns each of the first spaces covered by the first spatial information 61.

In a case that the device-installation information included in the space use information 63 concerns a first space (YES in Step S203), the setting part 52 then associates the first space with use information which is associated with the device-installation information in the space use information 63 to thereby define a second space in Step S204.

For example, the device-installation information implying an entrance door and an entrance tile included in the space use information 63 concerns the first space assigned with the space identification information X1 in the first spatial information 61. The setting part 52 associates the first space assigned with the space identification information X1 with use information of “ENTRANCE” which is associated with the device-installation information in the space use information 63. The device-installation information implying a washbasin included in the space use information 63 concerns the first space assigned with the space identification information X5 in the first spatial information 61. The setting part 52 associates the first space assigned with the space identification information X5 with use information of “WASHROOM” which is associated with the device-installation information in the space use information 63. The device-installation information implying a gas stove and a sink included in the space use information 63 concerns the first space assigned with the space identification information X10 in the first spatial information 61. The setting part 52 associates the first space assigned with the space identification information X10 with use information of “KITCHEN” which is associated with the device-installation information in the space use information 63. The device-installation information implying a dining table included in the space use information 63 concerns the first space assigned with the space identification information X11 in the first spatial information 61. The setting part 52 associates the first space assigned with the space identification information X11 with use information of “DINING ROOM” which is associated with the device-installation information in the space use information 63. The device-installation information implying a sofa included in the space use information 63 concerns the first space assigned with the space identification information X12 in the first spatial information 61. The setting part 52 associates the first space assigned with the space identification information X12 with use information of “LIVING ROOM” which is associated with the device-installation information in the space use information 63. The device-installation information implying a bed included in the space use information 63 concerns the first space assigned with the space identification information X7 in the first spatial information 61. The setting part 52 associates the first space assigned with the space identification information X7 with use information of “BEDROOM” which is associated with the device-installation information in the space use information 63. The device-installation information implying a bathtub included in the space use information 63 concerns the first space assigned with the space identification information X4 in the first spatial information 61. The setting part 52 associates the first space assigned with the space identification information X4 with use information of “BATHROOM” which is associated with the device-installation information in the space use information 63.

In a case that no device-installation information included in the space use information 63 concerns a first space (NO in Step S203), the first space is more likely to be a space that is not currently used but supposed to be used, or a space for multiple uses, which is used not for a specific purpose but according to the purposes. Accordingly, in this case, the setting part 52 then associates the first space with use information of “HALL” indicative of multiple space uses to thereby define a second space in Step S205. In the example in FIG. 5, the setting part 52 associates the first spaces assigned with the space identification information X6, X9 with the use information of “HALL”. In this regard, in Step S205, an input request may be transmitted to a registered user terminal and an input of use information by a user may be accepted.

Thus, the setting part 52 defines a plurality of second spaces by associating each of the first spaces covered by the first spatial information 61 with use information on the basis of the space use information 63 to generate second spatial information 64 covering the second spaces.

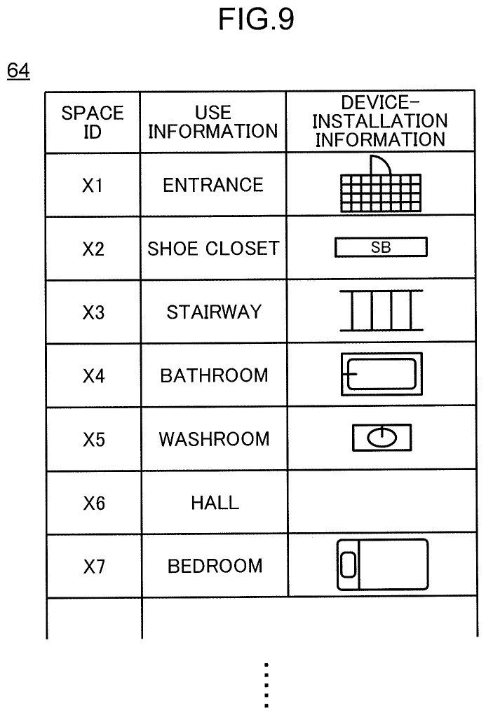

FIG. 9 is a diagram showing a first example of second spatial information 64. The setting part 52 generates second spatial information 64 such that the relevance table 62 shown in FIG. 6 is associated with use information. For example, the space identification information X1 such as a space ID is associated with the use information of “ENTRANCE” and the device-installation information indicative of an entrance door and an entrance tile. The space identification information X2 is associated with the use information of “SHOE CLOSET” and the device-installation information indicative of a shoe rack (SB). The space identification information X3 is associated with the use information of “STAIRWAY” and the device-installation information indicative of a stairway. The space identification information X4 is associated with the use information of “BATHROOM” and the device-installation information indicative of a bathtub. The space identification information X5 is associated with the use information of “WASHROOM” and the device-installation information indicative of a washbasin. The space identification information X6 is associated with the use information of “HALL”. The space identification information X7 is associated with the use information of “BEDROOM” and the device-installation information indicative of a bed.

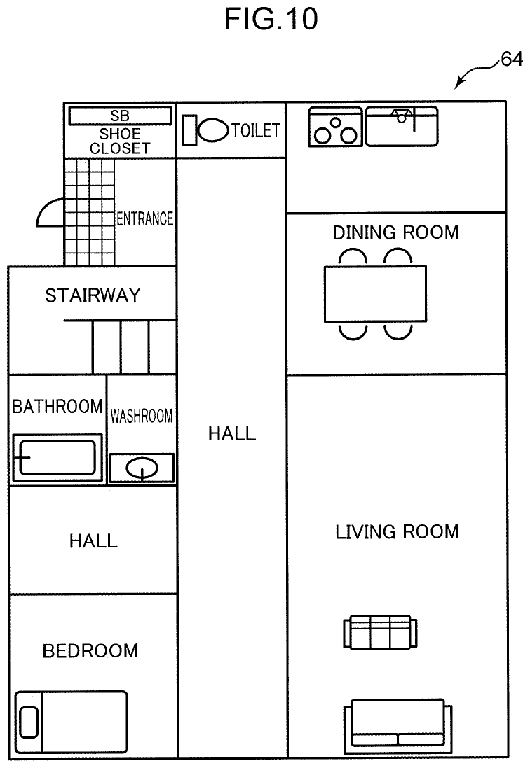

FIG. 10 is a diagram showing a second example of second spatial information 64. The setting part 52 generates second spatial information 64 such that space identification information X in the first spatial information 61 shown in FIG. 5 is replaced by use information for an association. The space identification information X1 is replaced by the use information of “ENTRANCE” for the association. The space identification information X2 is replaced by the use information of “SHOE CLOSET” for the association. The space identification information X3 is replaced by the use information of “STAIRWAY” for the association. The space identification information X4 is replaced by the use information of “BATHROOM” for the association. The space identification information X5 is replaced by the use information of “WASHROOM” for the association. The space identification information X6 is replaced by the use information of “HALL” for the association. The space identification information X7 is replaced by the use information of “BEDROOM” for the association. The space identification information X8 is replaced by the use information of “TOILET” for the association. The space identification information X9 is replaced by the use information of “HALL” for the association. The space identification information X10 is replaced by the use information of “KITCHEN” for the association. The space identification information X11 is replaced by the use information of “DINING ROOM” for the association. The space identification information X12 is replaced by the use information of “LIVING ROOM” for the association.

In the embodiment, the acquisition part 51 of the information processing part 50 acquires the first spatial information 61 including the division information and the device-installation information, and the space use information 63 associating the device-installation information and the use information with each other. The setting part 52 of the information processing part 50 defines a plurality of second spaces by associating each of the first spaces covered by the first spatial information 61 with use information on the basis of the space use information 63 to generate second spatial information 64 covering the second spaces. Thus, use information for each of the first spaces covered by the first spatial information 61 can be automatically set by use of the device-installation information included in the first spatial information 61. This can make the setting task easier and more efficient.

### Second Embodiment

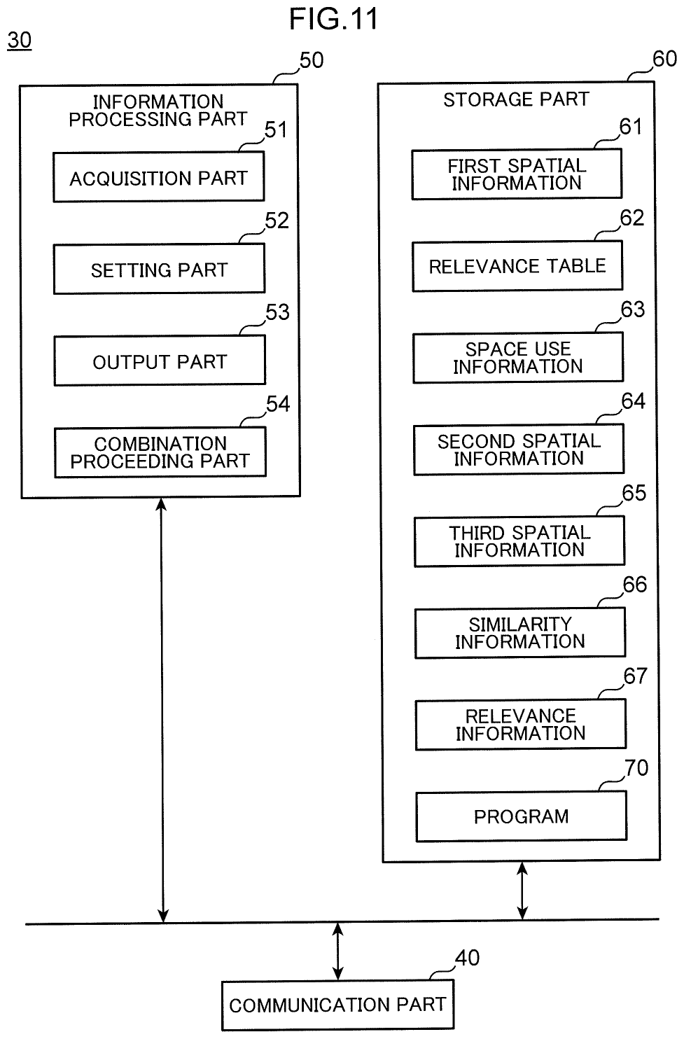

The second embodiment involves a combination of a plurality of second spaces based on a predetermined condition. FIG. 11 is a diagram briefly showing a structure of a server device 30 according to the second embodiment. On the basis of the configuration shown in FIG. 2, the information processing part 50 further includes a combination proceeding part 54, and the storage part 60 further stores third spatial information 65, similarity information 66, and relevance information 67. The combination proceeding part 54 defines a third space by combining a plurality of second spaces according to a predetermined condition to thereby generate third spatial information 65 covering the third space. The details of the similarity information 66 and the relevance information 67 will be described later.

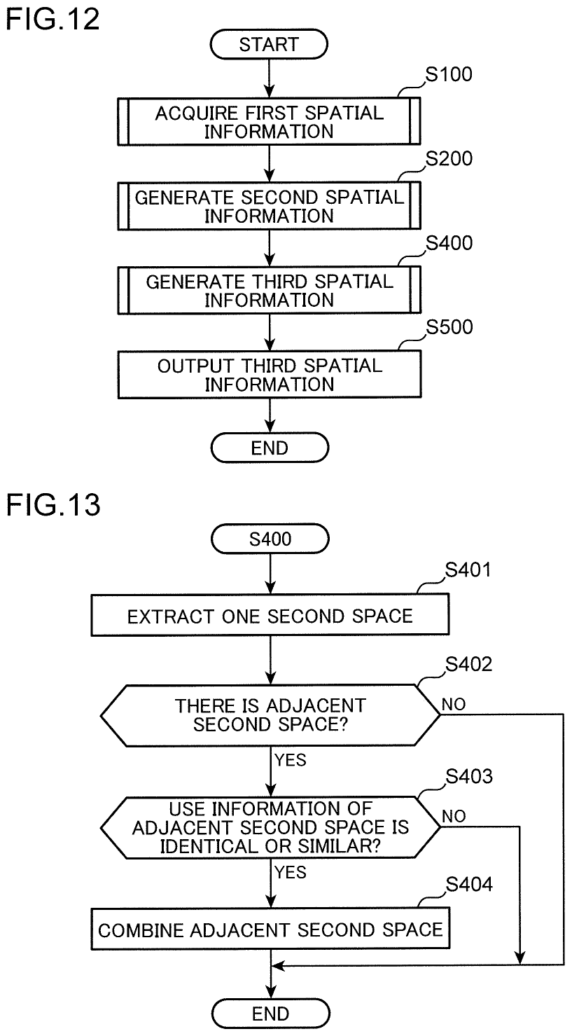

FIG. 12 is a flowchart briefly showing a flow of a process executed by the information processing part 50 of the server device 30 according to the second embodiment.

First, in Step S100, the acquisition part 51 acquires first spatial information 61 and stores the acquired first spatial information 61 in the storage part 60. The details of Step S100 are similar to those in FIG. 4.

Next, in Step S200, the setting part 52 defines a plurality of second spaces by associating each of the first spaces covered by the first spatial information 61 with use information on the basis of the space use information 63 to generate second spatial information 64 covering the second spaces. The details of Step S200 are similar to those in FIG. 7.

Next, in Step S400, the combination proceeding part 54 defines a third space by combining a plurality of second spaces according to a predetermined condition to thereby generate third spatial information 65 covering the third space. The details of Step S400 will be described later.

Next, in Step S500, the output part 53 outputs the third spatial information 65 generated by the combination proceeding part 54. The third spatial information 65 output from the output part 53 is stored in the storage part 60. The third spatial information 65 output from the output part 53 is also input to the communication part 40. The communication part 40 transmits the input third spatial information 65 to the integral controller 10 through the communication network 20. The communication part 40 may transmit the third spatial information 65 to a pre-registered communication terminal, e.g., a smartphone.

FIG. 13 is a flowchart showing in detail a first example of a proceeding of Step S400 shown in FIG. 12.

First, in Step S401, the combination proceeding part 54 extracts one second space from the second spatial information 64.

Next, in Step S402, the combination proceeding part 54 determines whether or not the second spatial information 64 has a second space (hereinafter, referred to as “adjacent second space”) adjacent to the second space (hereinafter, referred to as “extracted second space”) extracted in Step S401. The combination proceeding part 54 executes the determination in Step S402 by referring to adjacent space information in connection with the extracted second space, the adjacent space information being attached to the second spatial information 64 shown in FIG. 9 and indicative of an adjacent second space to each of the second spaces. Alternatively, the combination proceeding part 54 may execute the determination in Step S402 by image analysis on the second spatial information 64 shown in FIG. 10.

In a case that there is an adjacent second space (YES in Step S402), the combination proceeding part 54 then determines in Step S403 with reference to the similarity information 66 whether or not the use information of the adjacent second space is identical or similar to the use information of the extracted second space.

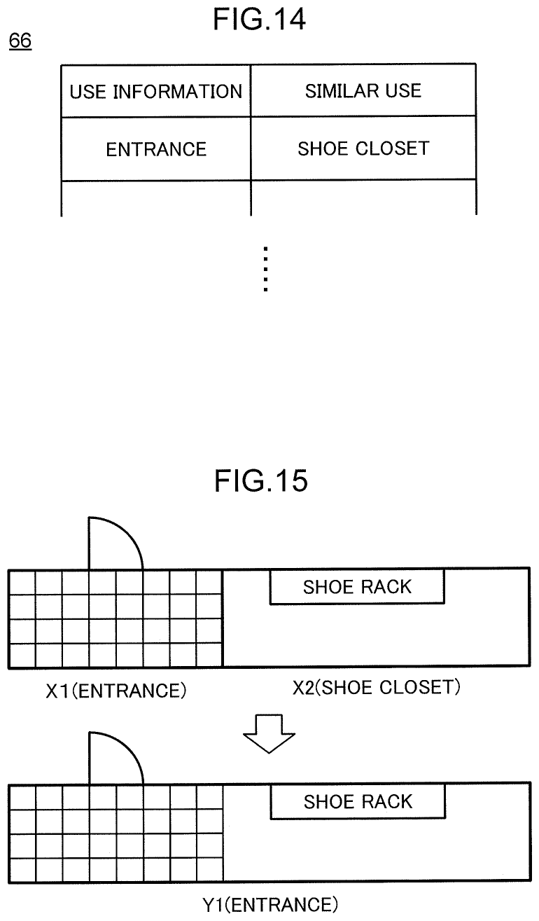

FIG. 14 is a diagram briefly showing an example of similarity information 66. In the similarity information 66, a similar use having similarity with certain use information is defined. In this example, the use information of “SHOE CLOSET” is defined as the similar use having similarity with the use information of “ENTRANCE”.

In a case that the use information of the adjacent second space is identical or similar to the use information of the extracted second space (YES in Step S403), the combination proceeding part 54 then combines the adjacent second space with the extracted second space to thereby define a third space in Step S404.

FIG. 15 is a diagram showing an exemplary combination proceeding. The second space assigned with the space identification information X1 and associated with the use information of “ENTRANCE” and the second space assigned with the space identification information X2 and associated with the use information of “SHOE CLOSET” are adjacent to each other and similar to each other in the use information. Therefore, the second space assigned with the space identification information X2 is combined with the second space assigned with the space identification information X1, so that a third space assigned with new space identification information Y1 and associated with the use information of “ENTRANCE” is defined.

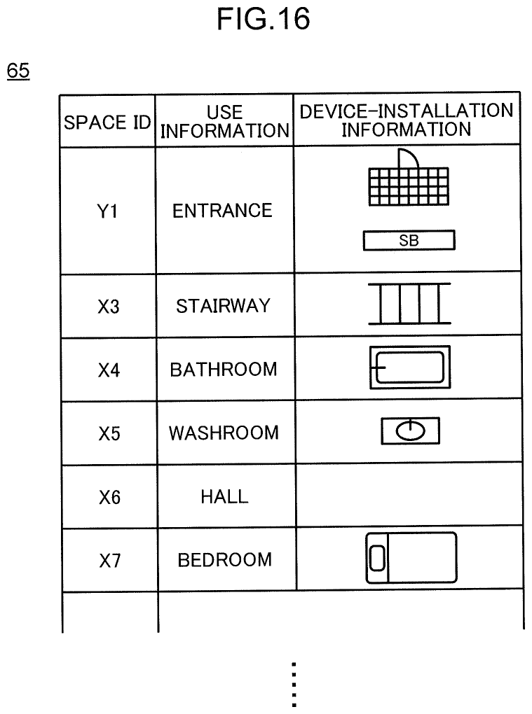

FIG. 16 is a diagram briefly showing an example of third spatial information 65. The combination proceeding part 54 combines the second space assigned with the space identification information X2 with the second space assigned with the space identification information X1 in the second spatial information 64 shown in FIG. 9, and defines a third space assigned with space identification information Y1 and associated with the use information of “ENTRANCE”, thereby generating third spatial information 65. The combination proceeding part 54 may generate third spatial information 65 as shown in FIG. 10.

In a case that there is no adjacent second space (NO in Step S402) or a case that the use information of the adjacent second space is neither identical nor similar to the use information of the extracted second space (NO in Step S403), the combination proceeding part 54 renews the extraction of a second space or ends the process, without executing Step S404.

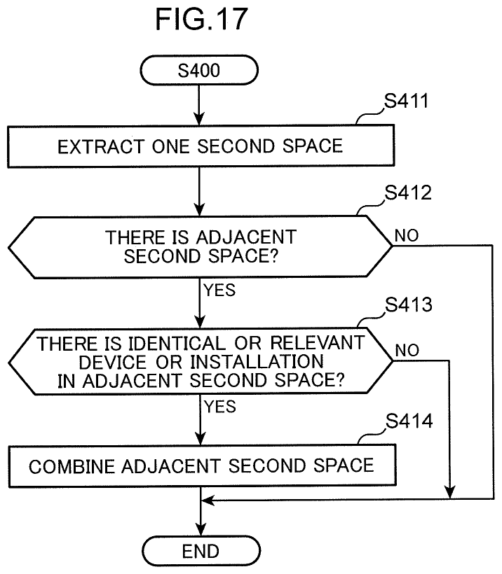

FIG. 17 is a flowchart showing in detail a second example of the proceeding of Step S400 shown in FIG. 12.

First, in Step S411, the combination proceeding part 54 extracts one second space from the second spatial information 64.

Next, in Step S412, the combination proceeding part 54 determines whether or not there is an adjacent second space to the extracted second space.

In a case that there is an adjacent second space (YES in Step S412), the combination proceeding part 54 then determines with reference to the relevance information 67 in Step S413 whether or not the adjacent second space has a device 11 or an installation 12 identical or relevant to a device 11 or an installation 12 disposed in the extracted second space.

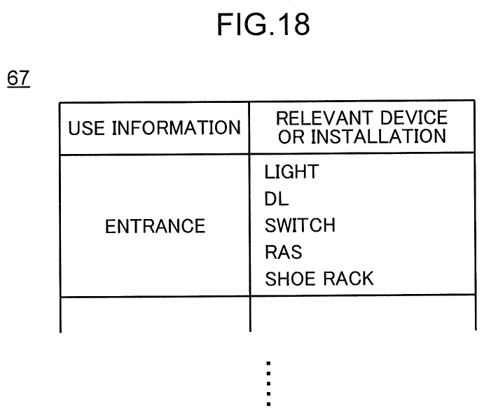

FIG. 18 is a diagram briefly showing an example of relevance information 67. In the relevance information 67, devices 11 or installations 12 relevant to each other for certain use information are defined. In this example, a light, a downlight (DL), a switch, a human detection sensor (RAS), and a shoe rack are defined as a device or an installation relevant to the use information of “ENTRANCE”.

In a case that a device 11 or an installation 12 disposed in the adjacent second space is identical or relevant to a device 11 or an installation 12 disposed in the extracted second space (YES in Step S413), the combination proceeding part 54 then combines the adjacent second space with the extracted second space to thereby define a third space in Step S414.

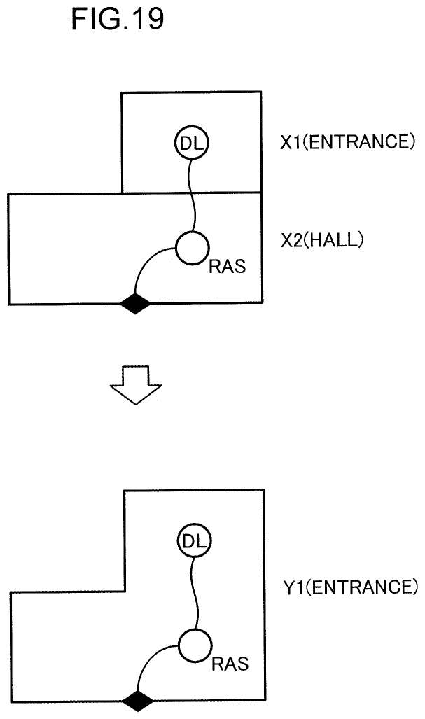

FIG. 19 is a diagram showing an exemplary combination proceeding. The second space assigned with the space identification information X1 and associated with the use information of “ENTRANCE” has a downlight (DL), and the second space assigned with the space identification information X2 and associated with the use information of “HALL” has a human detection sensor (RAS) and a switch (rhombic and black mark). The downlight, the human detection sensor, and the switch are connected by wires. The wire between the downlight and the human detection sensor is across the second space assigned with the space identification information X1 and the second space assigned with the space identification information X2. The two second spaces are adjacent to each other and have devices 11 or installations 12 relevant to each other. Therefore, the second space assigned with the space identification information X2 is combined with the second space assigned with the space identification information X1, so that a third space assigned with new space identification information Y1 and associated with the use information of “ENTRANCE” is defined. As another examples, in a case that one of the adjacent second spaces has a music player and the other of the second spaces has a speaker, the two second spaces are combined into a third space; in a case that two adjacent second spaces have respective air conditioners (or vents for air-conditioned air) that are controlled collectively, the two second spaces are combined into a third space.

In a case that there is no adjacent second space (NO in Step S412) or a case that the devices 11 or the installations 12 disposed in the adjacent second space are neither identical nor relevant to the devices 11 or the installations 12 disposed in the extracted second space (NO in Step S413), the combination proceeding part 54 renews the extraction of a second space or ends the process, without executing Step S414.

The embodiment enables optimized spatial management owing to the combination proceeding. Consequently, the usability for a user can be improved.

### INDUSTRIAL APPLICABILITY

The present disclosure is useful especially when applied to a home control system for use in a smart home with IoT technology.

### EXPLANATION OF REFERENCE NUMERALS

100 smart home
30 server device
50 information processing part
51 acquisition part
52 setting part
53 output part
54 combination proceeding part
60 storage part
61 first spatial information
62 relevance table
63 space use information
64 second spatial information
65 third spatial information
66 similarity information
67 relevance information
70 program

1. A space information output method, by an information processing apparatus, comprising:
acquiring first spatial information including division information indicative of divisions in a building and device-installation information indicative of a device or an installation disposed in a division;
acquiring space use information associating the device-installation information and use information indicative of a space use in connection with a device or an installation disposed in a space with each other;
generating second spatial information by associating the use information with the division information included in the first spatial information on the basis of the space use information; and
outputting the second spatial information, wherein
in the generation of the second spatial information,
the device-installation information included in the space use information is collated with the device-installation information for the division in the first spatial information, and
in a case that the device-installation information included in the space use information concerns the division covered by the first spatial information, the division is associated with use information which is associated with the device-installation information in the space use information, and
in a case that the device-installation information included in the space use information does not concern the division covered by the first spatial information, the division is associated with use information indicative of multiple space uses.

2. The space information output method according to claim 1, wherein
in the acquisition of the first spatial information,
a blueprint or a floor plan of the building is acquired,
a space separated by a wall or a partition in the blueprint or the floor plan is detected as a division, and
device-installation information in the division is detected.

3. The space information output method according to claim 2, further comprising:
assigning identification information to the division, and
creating a relevance table associating the identification information and the device-installation information with each other.

4. The space information output method according to claim 2, wherein the device-installation information includes any one of an illustration, a sign, and a name indicative of a placed device or installation in the blueprint or the floor plan.

5. The space information output method according to claim 1, wherein the space use information includes the use information indicative of at least one of an entrance, a washroom, a kitchen, a dining room, a living room, a bedroom, a bathroom, and a Japanese-style room.

6. A space information output method, by an information processing apparatus, comprising:
acquiring first spatial information including division information indicative of divisions in a building and device-installation information indicative of a device or an installation disposed in a division;
acquiring space use information associating the device-installation information and use information indicative of a space use in connection with a device or an installation disposed in a space with each other;
generating second spatial information by associating the use information with the division information included in the first spatial information on the basis of the space use information; and
outputting the second spatial information, the space information output method further comprising:
generating, in a case that the second spatial information includes a plurality of divisions adjacent to each other and assigned with identical or similar use information, third spatial information on combination of the plurality of divisions; and
outputting the third spatial information.

7. The space information output method according to claim 6, wherein the space use information includes the use information indicative of at least one of an entrance, a washroom, a kitchen, a dining room, a living room, a bedroom, a bathroom, and a Japanese-style room.

8. A space information output method, by an information processing apparatus, comprising:
acquiring first spatial information including division information indicative of divisions in a building and device-installation information indicative of a device or an installation disposed in a division;
acquiring space use information associating the device-installation information and use information indicative of a space use in connection with a device or an installation disposed in a space with each other;
generating second spatial information by associating the use information with the division information included in the first spatial information on the basis of the space use information; and
outputting the second spatial information, the space information output method further comprising:
generating, in a case that the second spatial information includes a plurality of divisions adjacent to each other and provided with identical or relevant devices or installations, third spatial information on combination of the plurality of divisions; and
outputting the third spatial information.

9. The space information output method according to claim 8, wherein the relevant device or installation includes a light, a wire connected to the light, and a switch connected to the wire.

10. The space information output method according to claim 8, wherein the space use information includes the use information indicative of at least one of an entrance, a washroom, a kitchen, a dining room, a living room, a bedroom, a bathroom, and a Japanese-style room.

11. A space information output apparatus comprising:
an acquisition part for acquiring first spatial information including division information indicative of divisions in a building and device-installation information indicative of a device or an installation disposed in a division, and space use information associating the device-installation information and use information indicative of a space use in connection with a device or an installation disposed in a space with each other;
a setting part for generating second spatial information by associating the use information with the division information included in the first spatial information on the basis of the space use information; and
an output part for outputting the second spatial information, wherein
the setting part
collates the device-installation information included in the space use information with the device-installation information for the division in the first spatial information,
associates, in a case that the device-installation information included in the space use information concerns the division covered by the first spatial information, the division with use information which is associated with the device-installation information in the space use information, and
associates, in a case that the device-installation information included in the space use information does not concern the division covered by the first spatial information, the division with use information indicative of multiple space uses.

12. A computer-readable recording medium recording a program for causing an information processing apparatus to serve as:
acquisition means for acquiring first spatial information including division information indicative of divisions in a building and device-installation information indicative of a device or an installation disposed in a division, and space use information associating the device-installation information and use information indicative of a space use in connection with a device or an installation disposed in a space with each other;
setting means for generating second spatial information by associating the use information with the division information included in the first spatial information on the basis of the space use information; and
output means for outputting the second spatial information, wherein
the setting means
collates the device-installation information included in the space use information with the device-installation information for the division in the first spatial information,
associates, in a case that the device-installation information included in the space use information concerns the division covered by the first spatial information, the division with use information which is associated with the device-installation information in the space use information, and
associates, in a case that the device-installation information included in the space use information does not concern the division covered by the first spatial information, the division with use information indicative of multiple space uses.
